(19) United States
(12) Patent Application Publication
(10) Pub. No.: US 2025/0231220 A1
(43) Pub. Date: Jul. 17, 2025

(54) ACCELERATION INSIGHTS, ENHANCING EFFICIENCY, AND ENABLING PREDICTIVE MAINTENANCE IN TEST AND MEASUREMENT SYSTEMS USING ARTIFICIAL INTELLIGENCE ASSISTANT

(71) Applicant: Tektronix, Inc., Beaverton, OR (US)

(72) Inventors: Anurag Koodali Thazathvetil, Bengaluru (IN); Krishna N H Sri, Bengaluru (IN); Raghavendra Hegde, Bengaluru (IN); Vivek Shivaram, Bengaluru (IN); Madhusudan Acharya, Bengaluru (IN)

(21) Appl. No.: 19/005,268

(22) Filed: Dec. 30, 2024

(30) Foreign Application Priority Data
Jan. 15, 2024 (IN) 202421002876

(51) Int. Cl. G01R 13/02; G06N 20/00

(52) U.S. Cl. CPC G01R 13/0218; G06N 20/00

(57) ABSTRACT

A test and measurement instrument includes one or more ports to connect to a device under test (DUT), a user interface having one or more controls, a display, a storage, one or more processors to receive test signals from the DUT through the one or more ports as test of the DUT, use the test signals to generate test data, display test data on the display, display a control button on the user interface indicating that an artificial intelligence (AI) assistant is available, receive an input through the control button to start the AI assistant, provide regions on the user interface to allow the user to interact with the AI assistant, and apply a machine learning model represented by the AI assistant to provide the user with additional information related to one or more of the test and the DUT.

### CROSS-REFERENCE TO RELATED APPLICATIONS

This disclosure claims priority under 35 U.S.C. § 119 to Indian Provisional Patent Application No. 202421002876, titled “ACCELERATION INSIGHTS, ENHANCING EFFICIENCY, AND ENABLING PREDICTIVE MAINTENANCE IN TEST AND MEASUREMENT SYSTEMS USING ARTIFICIAL INTELLIGENCE ASSISTANT,” filed on Jan. 15, 2024, the disclosure of which is incorporated herein by reference in its entirety.

### TECHNICAL FIELD

This disclosure relates to artificial intelligence (AI), more particularly to an AI assistant for use in test and measurement systems to accelerate insights, enhance efficiency, and enable predictive maintenance.

### BACKGROUND

AI and machine learning (ML) have emerged as powerful tools for data analysis and the extraction of insights from test data. The AI-driven models can autonomously interpret complex data patterns, enabling more efficient and accurate analysis of test results. Machine Learning, with its capacity to adapt and improve performance over time, plays a crucial role in predictive maintenance, identifying potential equipment failures before they occur.

Currently ML and AI can make these predictions and perform some of this type of data analysis but currently they can take long durations of test. In addition, current approaches use pre-trained models. Using pre-trained models requires gathering of large amounts of training data, training the model, and then validation. This process takes longer than desired and affects the user's workflow to accommodate the testing cycle.

### BRIEF DESCRIPTION OF THE DRAWINGS

FIG. 1 shows an embodiment of an AI assistant architecture.

FIG. 2 shows an embodiment of AI assistant training settings in a measurement configuration.

FIG. 3 shows an embodiment of a user interface showing an AI assistant indicating required changes to a current test.

FIG. 4 shows an embodiment of an AI assistant in accompanying mode to help users to change a particular configuration to get an accurate measurement.

FIG. 5 shows an embodiment of a user interface showing a change of configuration solving a measurement warning and enabling an accurate measurement value.

FIG. 6 shows an embodiment of a user interface resulting from an input on Assistant icon for natural language ‘AI Assistant Interface’.

FIG. 7 shows an embodiment of a user interface resulting from an input from the user interface to chat with an ‘AI Assistant Interface’.

FIG. 8 shows an embodiment of a chat panel with a suggested action button.

FIG. 9 shows an embodiment of an AI Assistant-suggested phasor diagram added with DQ0 component for advanced analysis.

FIG. 10 shows an embodiment of a suggested control loop response (Bode plot) with extrapolated data for frequencies beyond 100 kHz.

FIG. 11 shows an embodiment of a flowchart for an AI assistant.

FIG. 12 shows an embodiment of a training and validation efficiency plot.

### DETAILED DESCRIPTION

The embodiments herein involve an AI-enabled test and measurement system that elevates the capabilities of test and measurement systems, providing unparalleled insights, improving testing and cost efficiency. The embodiments here can autonomously interpret complex data patterns, enabling more accurate analysis of test results. The embodiments here improve performance over time, and play a crucial role in predictive maintenance, and can identify potential equipment failures before they occur. The embodiments employ machine learning models that develop and train in real-time as a user continues to use the test and measurement instrument during design and validation.

The embodiments here involve an “AI assistant,” which refers to a machine learning model. The discussion here uses these terms interchangeably, so references to the AI Assistant refer to the user interface to the machine learning model. Unlike previous machine learning models, the embodiments here do not alter the user's workflow. As the user performs tests on devices under test (DUT), the embodiments gather data from the usage of the test and measurement instrument by the user to first define and create the model, and then train the model. The embodiments provide a model deployable across multiple test and measurement endpoints, allowing for consistent results across multiple instruments. Version control allows other endpoints to update the machine learning model without overwriting previous versions. Similarly, the embodiments extend the model to operate across multiple measurements, taking advantage of the same data capture and providing insights. External users to the system that includes all the endpoints, and the model storage, can use a subscription service to allow those external users access to machine learning models for their needs.

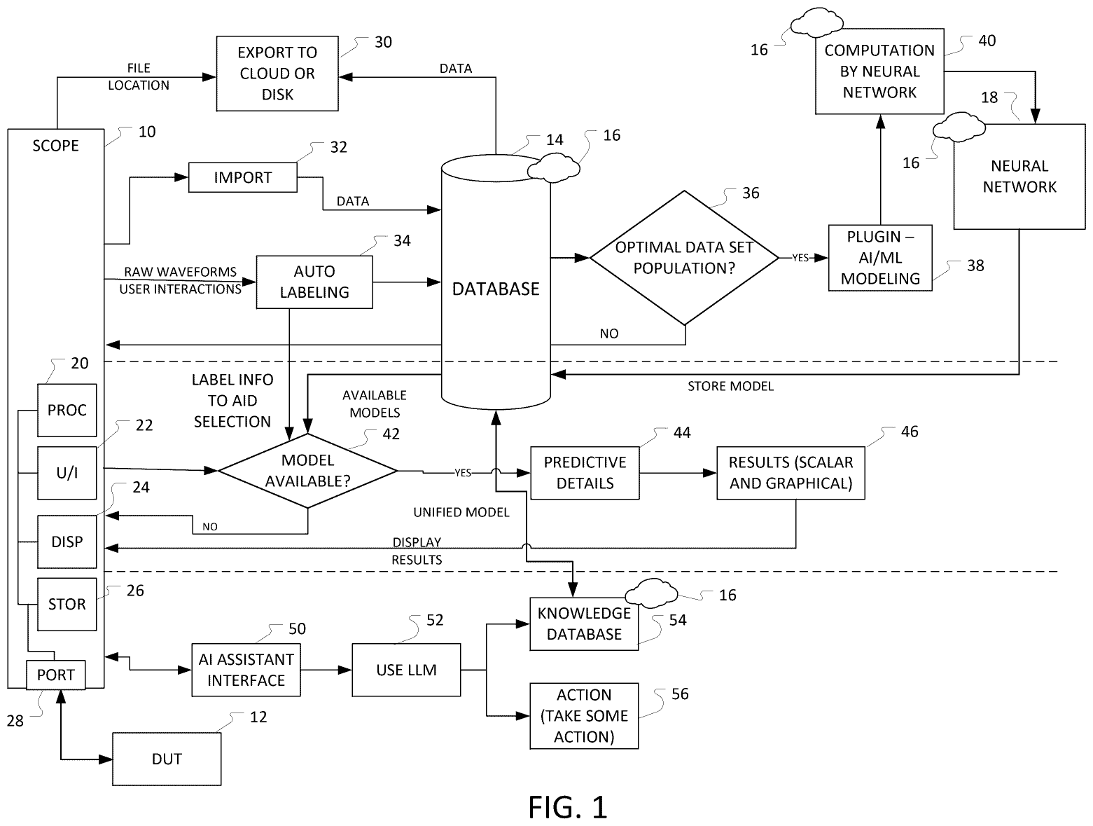

FIG. 1 shows an architecture of an embodiment of a system that creates and employs an embodiment of an AI assistant. The instrument 10, here identified as an oscilloscope or “scope,” may comprise any test and measurement instrument. No limitation to an oscilloscope should be implied. In a testing environment, the scope 10 connects to the DUT 12. The scope may contain one or more processors such as 20, a user interface 22 having one or more controls, a display 24, and a storage 26. The controls may comprise buttons, knobs, and sliders, as examples, and may reside on the instrument body, as touch “buttons” on the display as part of the user interface, or both. The display may comprise at least a part of the user interface. The reference to storage may comprise both local storage and a link to external storage, including one or more databases such as 14, or cloud storage 16. The cloud storage may connect to many different elements of the architecture, but more than likely at least the database 14 and the neural network 18.

As the user operates the test and measurement instrument 10, the instrument will receive test signals form the DUT 12. In some cases, the one or more processors 20 cause signals to be applied to the DUT 12 to start the test. The DUT 12 will generate test signals in response to the signal applied to it. In other cases, the instrument will receive test signals from the DUT without needing to apply signals to the DUT to start the test. The test signals received by the instrument may comprise analog or digital signals received through the port 28. In one common example, the DUT 12 generates analog signals and the instrument 10 converts them into test data, such as a waveform. The instrument then displays the test data on the instrument display.

During employment of the test and measurement instrument as set out above, as an example, the instrument would export the test data, and associated metadata at 30. The metadata may include user inputs, scope and probe parameters, the state of technology such as standards and versions, voltage levels, currents, temperatures, and other operating parameters. The scope also imports the data at 32 into the database 14. The raw waveforms and user interactions undergo auto labelling at 34. Auto labelling classifies and removes unwanted data not useful to further analysis suggestions. The auto labelled data is also sent to the database 14. The system may employ efficient storage management by removing the unwanted data, and compressing, serializing, and saving in real time on the cloud, on the device, or in one or more databases. The trained weights are portable and may include version control within the organization.

Since oscilloscope firmware receives sampled analog data, minimal labelling is performed at the firmware level about characteristics of data. These labels may include Sample rate, time/frequency domain of data, technology tested, data based on probe used, etc. Every data accepted by oscilloscope is classified based on usage pattern meta data and user suggestion to model. The labelling system according to some embodiments of the disclosure may include a supervision block which will perform weak labelling of data with probabilistic values.

For each analysis of technology, there may be a classifier hosted in oscilloscope. As an example, the sequential ensemble technique may be used to combine each technology classifier to reach final classification. With the waveform data classified to probable technology, suggestion of measurements, plots and predictive analysis are provided for waveform data.

Returning to FIG. 1, this information is also used to determine if enough data is available to select an appropriate model at 36. The architecture may include an ability to create a model using a plug-in, or predefined program at 38. Returning to 36, if not enough data has become available, the process waits until more data is available, shown by the return path to the scope. If an appropriate model is available, the neural network 18 performs computations at 40 to select the appropriate model for the neural network 18.

The pseudocode below shows one embodiment of extraction of features from the data, collection of data samples, and selection of the model. It also shows validation and a decision whether the model is ready to user or needs more data.

Wfm[1 : n] = Acquire (Ch[1 : n])
Data_Cleaning( ) %% pre-processing

| | |
|---|---|
| MetaData = Extract_MetaData(Wfm[1 : n]) | %% additional information from the waveform like |
| | %% Configurations, Sig, GaN, temperature |

```
[ feat₁, feat₂, ... featₙ] = Extract_Features(Wfm[1 : n])
Wait_For_Enough_Samples_To_Start_Modelling( ) %% Collect the data samples, as user
continues to use Oscilloscope. This will be done until we have enough samples to create the
Model.
structModel = ML_Modelling(feat₁, feat₂, ... featₙ, MetaData)
Decide_Number_Of_Layers_BasedOnTechnology
MultiLayer_DeepNetwork( ) %% LMS Convolutional Neural Network, RELU, Linear
convolutional, PRE-TRAINED models from MATLAB.
Decide_Model_To_Choose %% Automatically choose the model based on the technology and
complexities. Based on the training data and cross validation data, the optimal model will be
chosen.
Cross_Validation_Test( )
Model_Results_With_Confidence_Percentage( )
  Confusion_MatrixPlot( )
RetrainModel ( ) %% if the gap between predicted and measured results, use that data
and feature set to fine tune the model parameters.
Model_ReadyToUse( )
  Provide_Additional_Info_With_GraphicalPlots( )
  Required_Waveform_DataReady( )
```

When the appropriate model is available at 42, the model operates on the data gathered at the instrument to provide predictive details at 44 and produces graphical and scalar results at 46. Once the model has enough data to train itself and operate, an Al assistant interface 50 will become available on the instrument interface. As the user interacts with Al assistant, the AI assistant may employ a large language model LLM at 52 to take an action at 56 and to update the knowledge database at 54.

The system architecture has the flexibility to store elements of the system on the instrument, in the cloud, or on another computing device connected to the instrument. Those elements of the system that may reside in the cloud have a cloud designation 16.

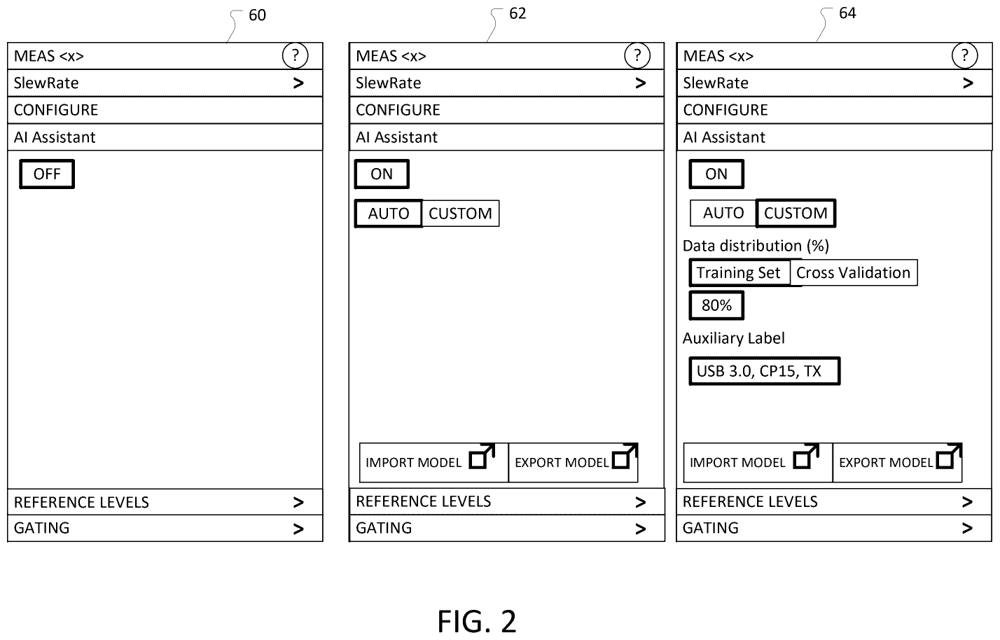

FIG. 2 shows an embodiment of a measurement configuration for training the AI Assistant. The first panel 60 shows the configuration screen with the training process OFF. Selected options in the following screens will have a darker line surrounding them, as shown surrounding the OFF in panel 60. The second panel 62 shows that configuration is ON, and the user has selected AUTO configuration. This would cause the system to train the AI assistant in a preconfigured, automatic manner. Panel 64 shows an embodiment of some designations for CUSTOM training. The user has set the data distribution percentage between the training set and the cross validation set at 80 percent for training. The user can configure the portions of the data set used for the training and validation. The user has also selected a set of labels for the data for the auto labelling process discussed above. The lower part of the panels in which the AI Assistant training is ON, the user has the option to Import Model to bring the model in from the model storage, which may occur when the model already exists and is undergoing retraining or fine tuning, as examples. The user can also Export Model when the retraining and/or fine tuning has completed.

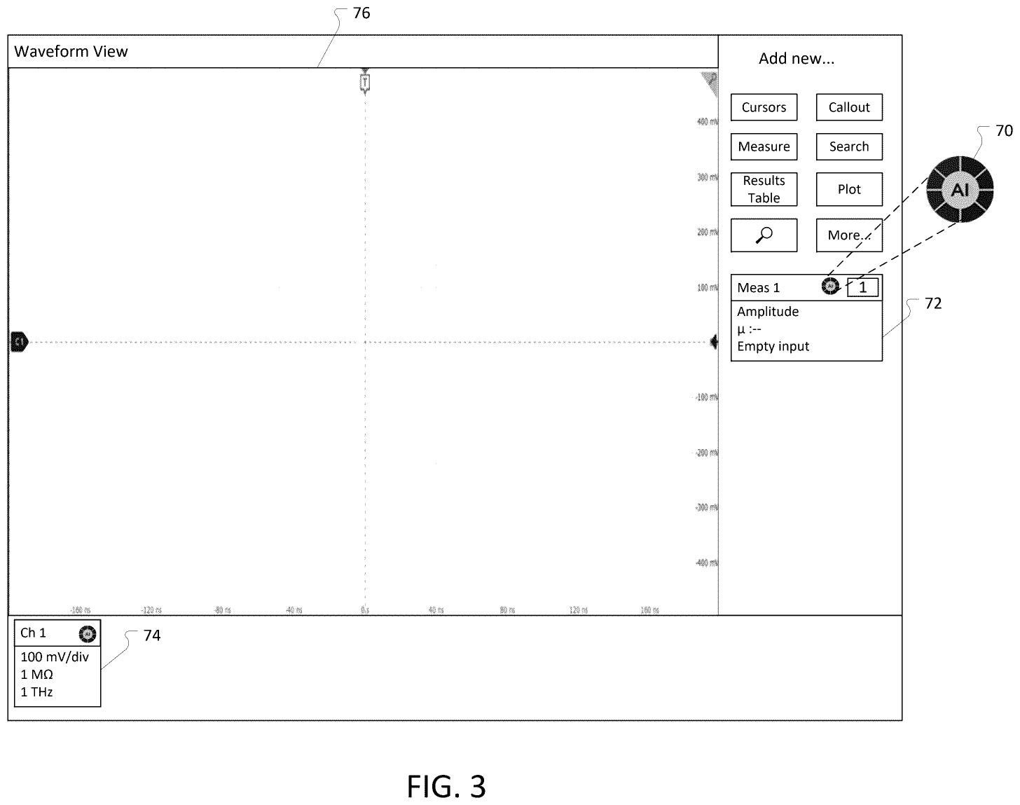

In the following figures, the availability of the AI Assistant appears as an AI Assistant Icon, shown at 70 in FIG. 3 both as it appears on the screen and in exploded view. In some embodiments, user interactions with the AI Assistant may have different options. For example, the embodiments may employ three known inputs from a mouse, a double click, a single click, or a right click. Each of these inputs would result in a different response from the AI Assistant. In one option, when the user selects one of the above inputs such as the double click, the AI Assistant may automatically perform the action indicated by the location of the AI Assistant icon. In another option, such as a single click, the AI Assistant may enter an “accompany” mode, in which the AI Assistant guides the user through the steps for the user to perform the indicated action. In another option, such as a right click, the AI Assistant may open a chatbot and allow the user to ask questions. This will more than likely involve the LLM mentioned above, to allow the AI Assistant to “understand” the questions and provide answers.

As a first example of an interaction with the AI Assistant, the AI Assistant indicates that the current configuration requires changes to acquire the waveform and perform a measurement. The issue can be seen in the output window 76. In this discussion, the output takes the form of a waveform, except that no waveform appears. The appearance of the AI Assistant icon 70 in the measurement badge “Meas 1” 72 indicates that the AI Assistant has a solution for the empty input. Similarly, the AI Assistant icon appears at the Ch 1 badge 74. The user can click on either icon in one of the three input modes discussed above. One should note that a typical instrument display has many other items displayed than are shown in FIGS. 3-10. These figures do not show these to simplify the views, but do not imply that these items are not present in the following figures.

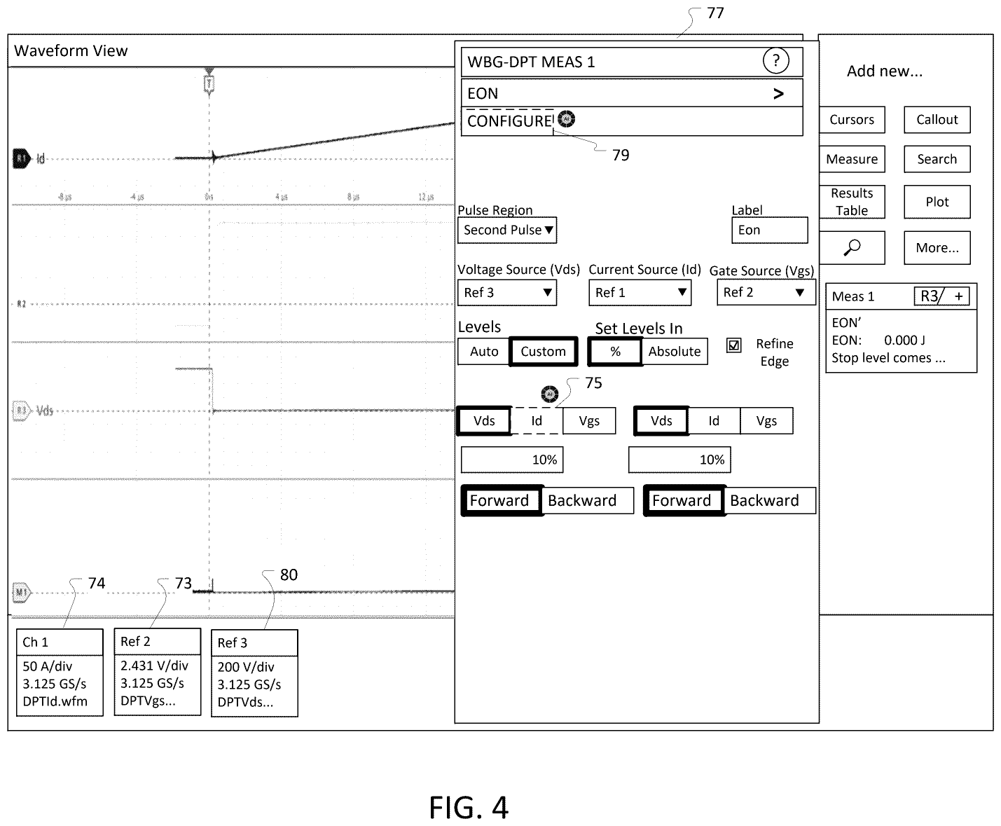

FIG. 4 shows the AI Assistant entering into an “accompanying” mode. This mode allows the AI Assistant to guide the user through the process of correcting the measurement configuration. The AI Assistant launches the configuration window 77 that shows the current configuration previously selected by the user. The AI Assistant indicates the settings that need to be changed. In the configuration window, the AI Assistant indicates that the user should select the CONFIGURE button 79, highlighted by the dashed lines. The AI Assistant also indicates that the user should change the setting from Vds to Id at 75. FIG. 4 also shows badges in the lower bar that display Ch 1, 74, Ref 2 73, and Ref 3 80. Note that these windows will not be shown in later figures.

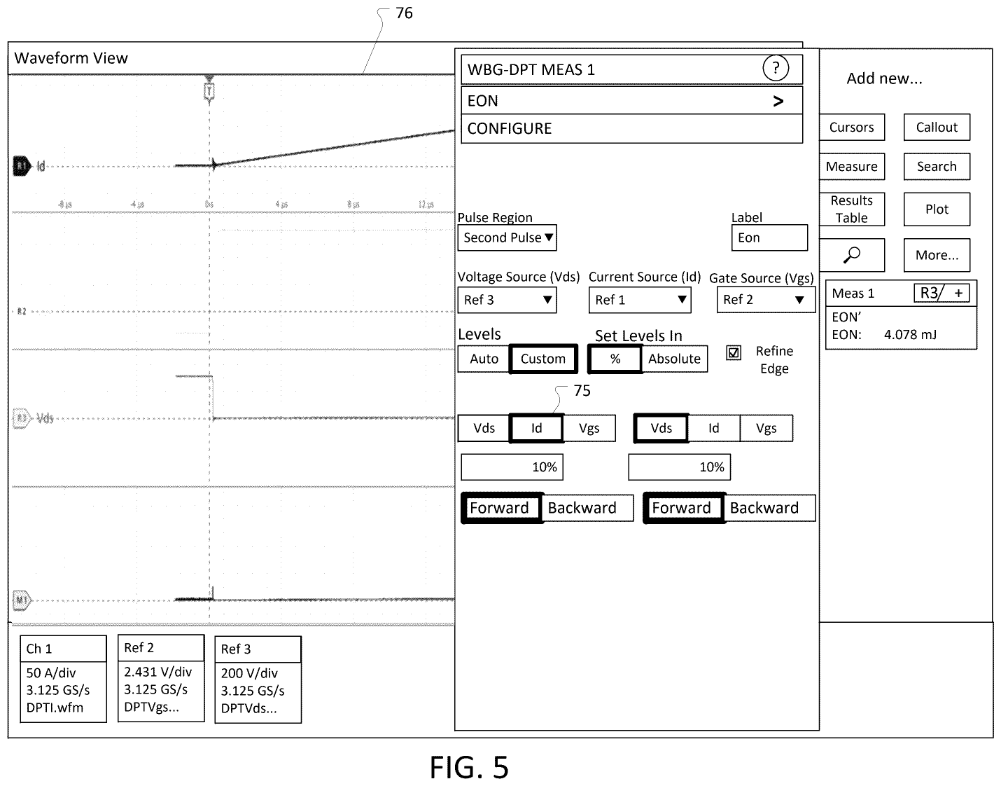

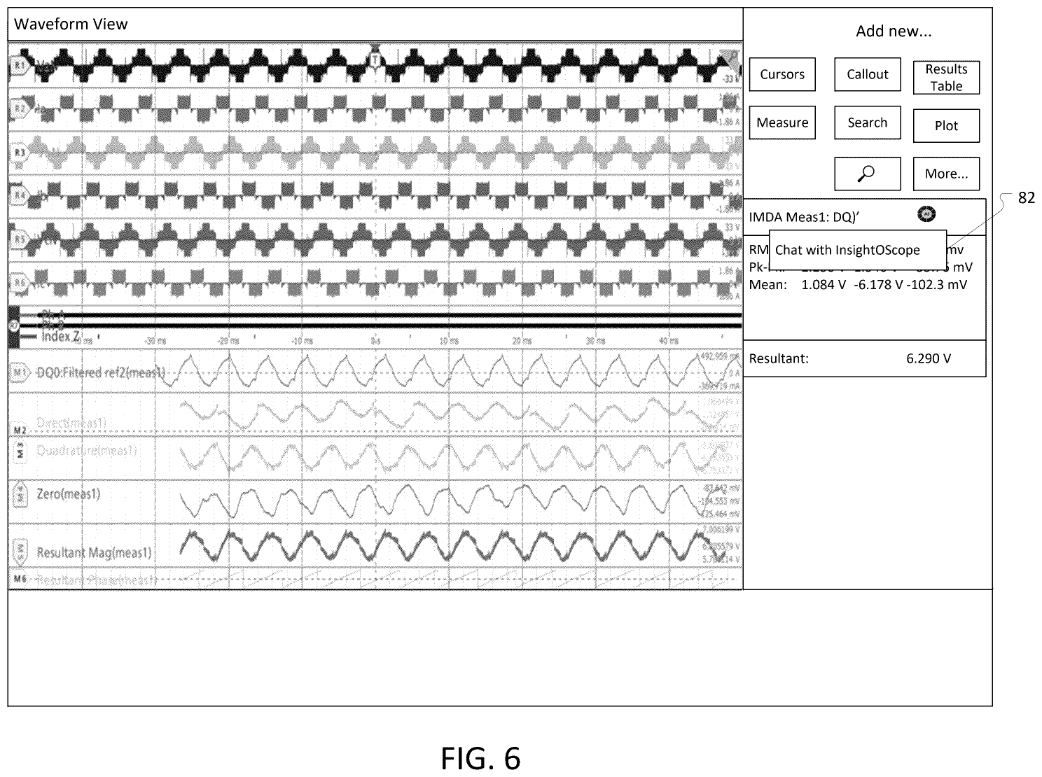

FIG. 5 shows the change to the setting at 75. The partially hidden output window 76 shows that waveforms now appear. FIG. 6 shows another example of interactions with the AI Assistant. In this example, the user has chosen to chat with the AI Assistant shown at 82.

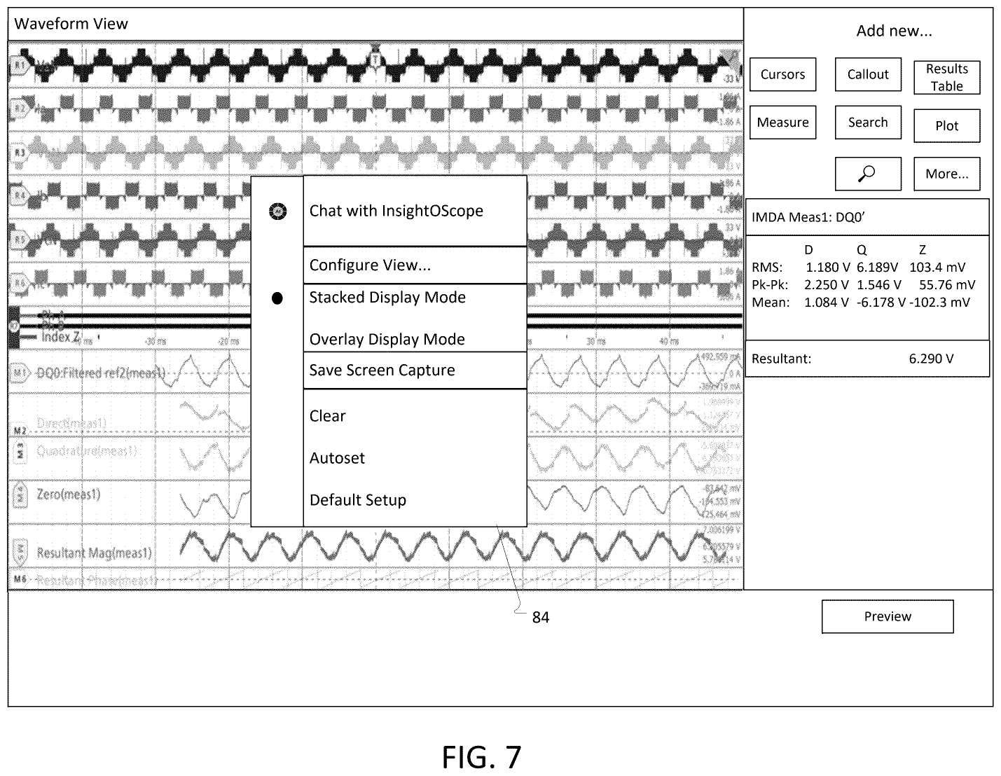

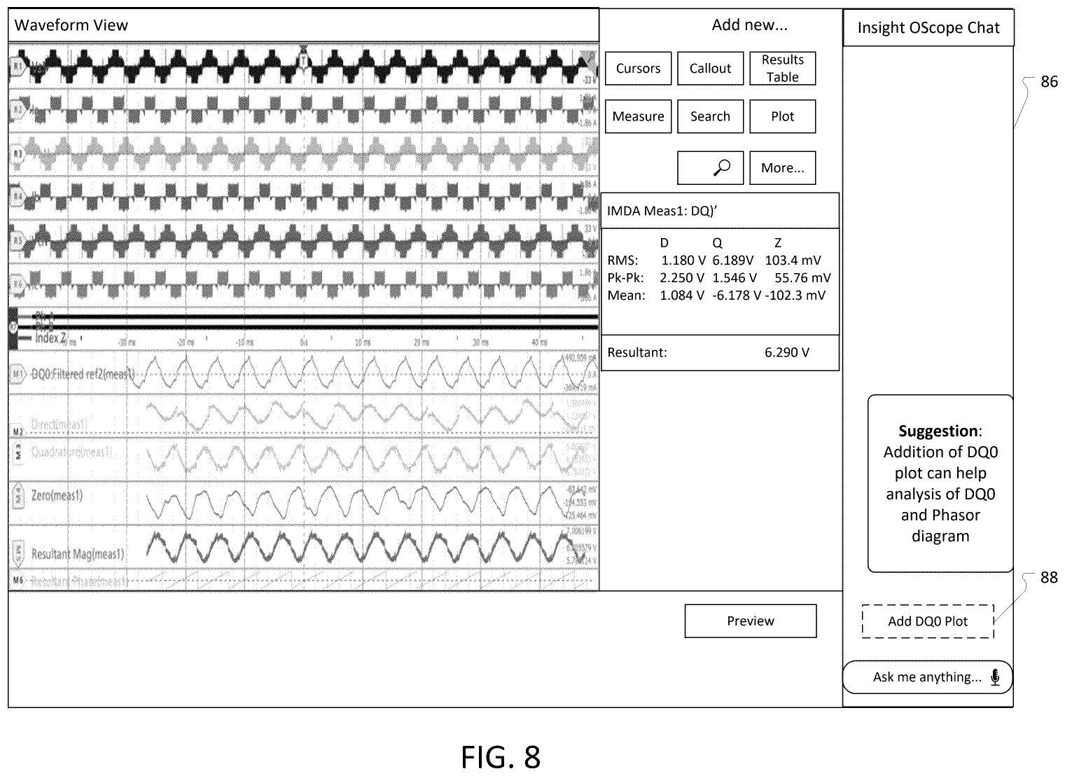

FIG. 7 shows the window 84 that allows the user to select to chat with the AI Assistant. FIG. 8 shows the chat window 86 as part of the display. The chat window provides the AI Assistant the ability to make suggestions and provide a way for the user to take an action to implement the suggestion. In the example give in FIG. 8, the AI Assistant has recommended that the user should add an DQ0 plot to aid in analysis. The AI Assistant has also provided a button 88 to make that addition.

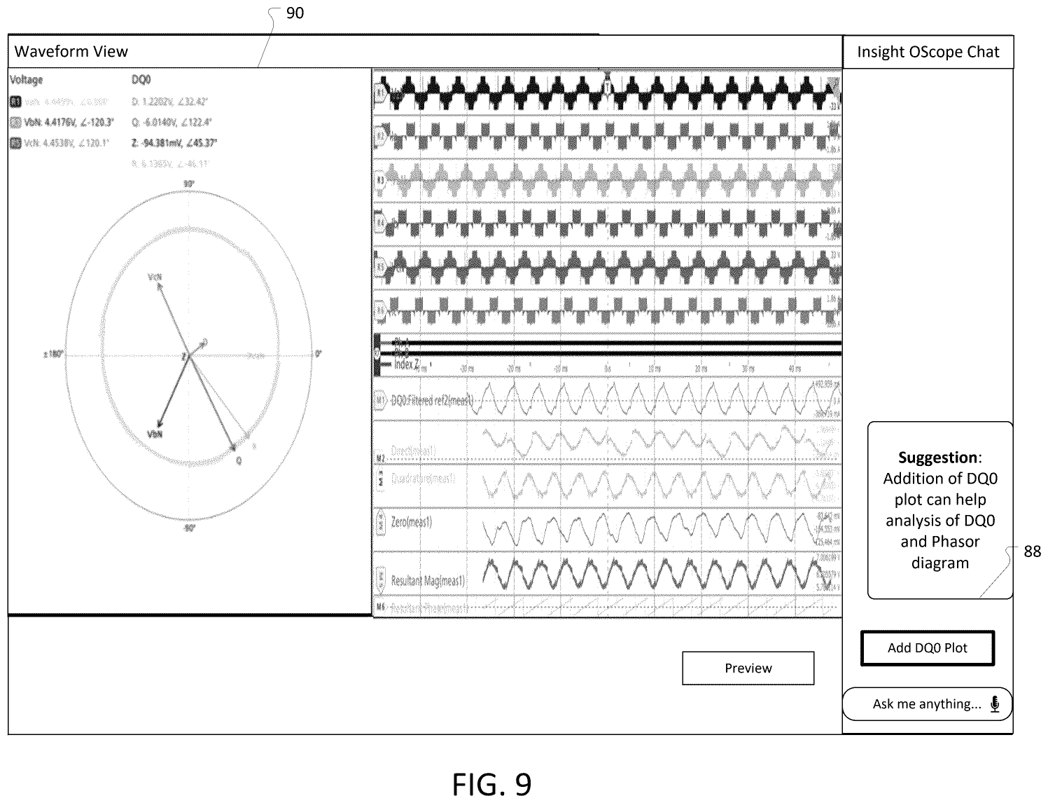

FIG. 9 shows the resulting DQ0 plot and phasor diagram 90. One should note that in FIG. 9 the center window of the display in FIG. 8 has been removed to allow for more room for the phasor diagram and the chat window. The display would still show the center window.

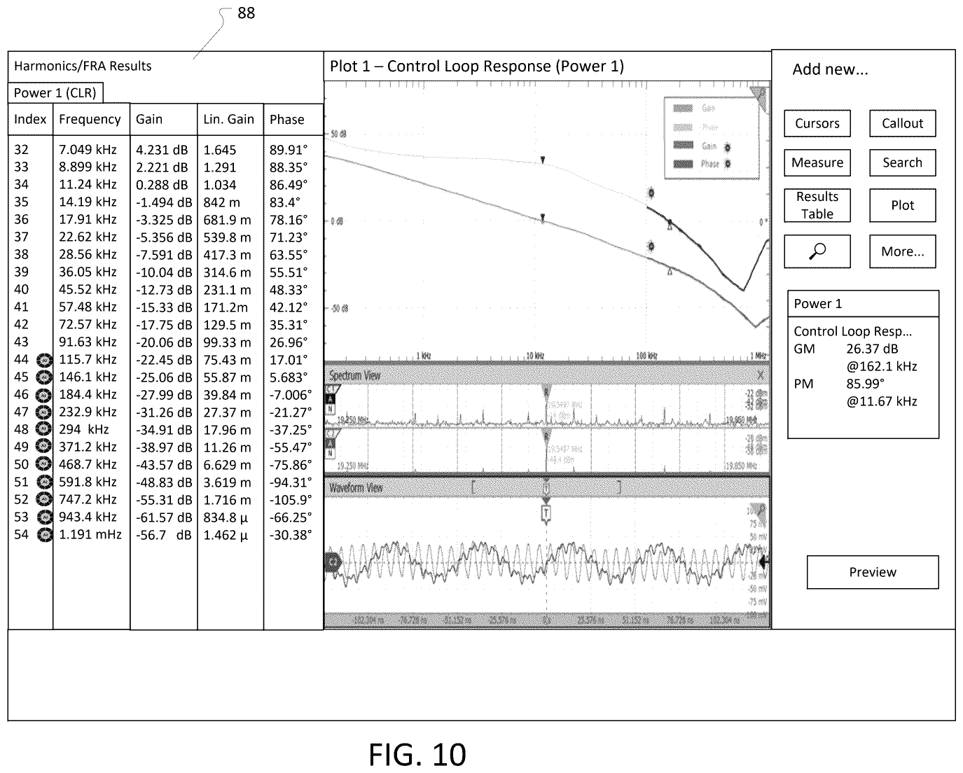

As discussed, the AI Assistant has the capability to predict results of measurements that the instrument did not actually make or calculate. FIG. 10 shows an example of this. As can be seen in the Harmonics/FRA Results window 88, the instrument has calculated Index, Frequency, Gain, Linear Gain, and Phase for multiple indices 32-43. As shown by the AI Assistant icon adjacent indices 44-54, the AI Assistant has predicted those measurements rather than needing the instrument to actually make those calculations. The AI Assistant has extrapolated that data from the previous measurements. This saves users large amounts of time. In reliability tests, very long events, sometimes greater than one million events are captured and take tens of thousands of hours of test times, computed across a range of operating parameters. The approach using the embodiments will help to predict with lesser data sets as shown above and is not limited to one measurement but can extend to multiple measurements.

FIGS. 3-10 shows examples of some of the features of the AI Assistant. These examples are not intended to demonstrate all the capabilities of the AI Assistant, they are merely intended as examples.

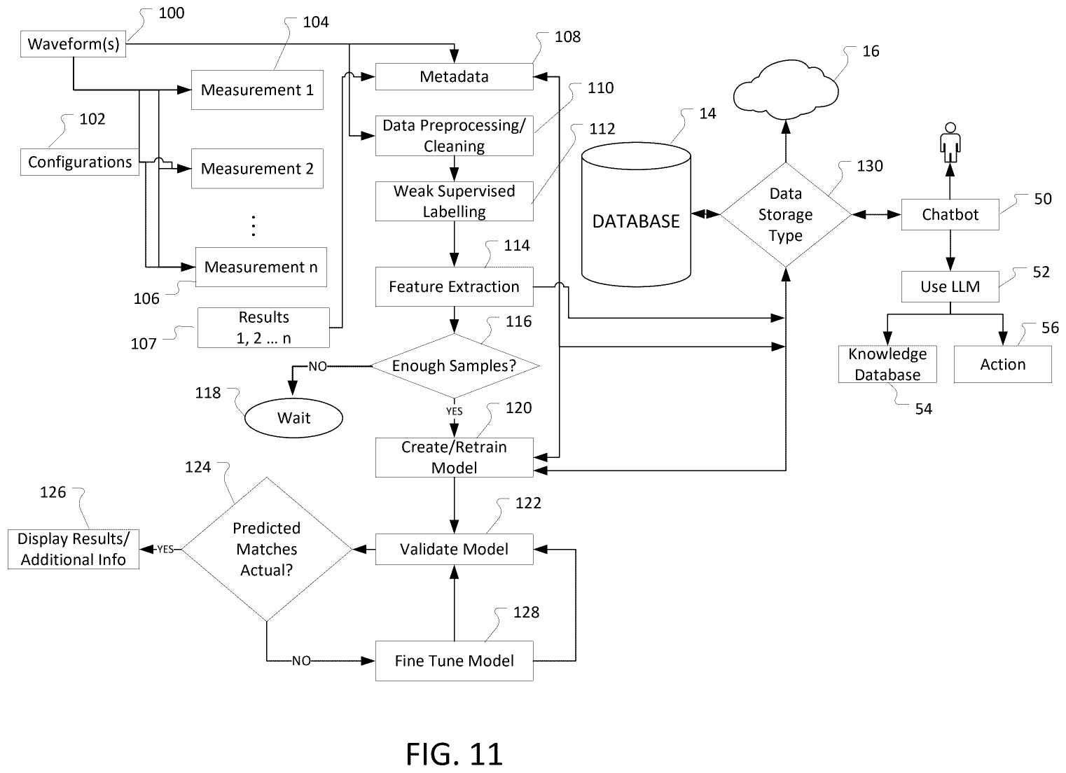

FIG. 11 shows a flowchart of an embodiment of the AI Assistant. Similar to the system architecture of FIG. 1, the process begins with the capture of the test data. In the example of FIG. 11, the test data takes the form of waveforms 100. The waveforms 100 and configurations 102 are used to take measurements 1 through n, 104 through 106. The waveforms undergo data preprocessing and cleaning 110. The results 107 and the other information makes up metadata 108. As discussed above the data undergoes weak labelling at 112 as part of the auto labelling process, and feature extraction 114.

The labelling system includes a supervision block to perform weak labelling with probabilistic values. For each analysis of technology, the instrument may host a classifier. As an example, the sequential ensemble technique may combine each technology classifier to reach final classification. With the test data classified as probable technology, the AI Assistant can make suggestions of measurements, plots, and predictive analysis for test data.

Returning to the flowchart, at 116, the process determines whether or not there are enough samples. If no, the process continues and waits at 118. If there are enough samples at 116, the process creates the model on the initial process or retrains/fine tunes the model at 120. The model is then validated at 122. If the predicted values match the actual values at 124, the AI Assistant can display the results and make other information available at 126. If the match result fails at 124, the model may undergo fine tuning at 128 until the result at 124 passes.

As used here the term “test data” refers to the data from the test, such as that represented by the waveform. As used here, the term “operational data” refers to the test data after undergoing preprocessing/cleaning, auto labelling and feature extraction, as this is the data upon which the model operates. The data associated with the test, including the test configuration, the measurements, results, and possibly other comprises the metadata.

The operational data and the metadata are saved in the database 14. The user can select the data storage type at 130, between the database 14 and the cloud 16. The data storage provides the user interface 50 from FIG. 1, in this instance as a chatbot, which uses the LLM at 52, to store information in knowledge database 54 and to take action at 56. This flowchart constitutes one embodiment of a process flow as an example. No limitation to any particular implementation or order of these processes is intended, nor should any be implied.

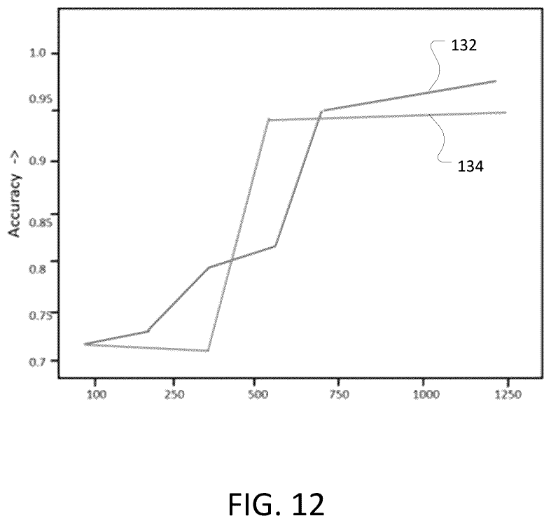

As mentioned above, the user can configure the portions of the training data gathered during operation between training and validation. The test and measurement instrument can provide plots of such as an efficiency plot, a loss plot, and histograms of the machine learning model's performance based upon the analysis. FIG. 12 shows an efficiency plot between the training accuracy 132 and the validation accuracy 134.

In this manner, the AI Assistant expands the capabilities of the test and measurement instruments. Advantages include reducing the testing times and provide predictive measurement result interpretation to the designers and validation engineers. The user can easily get additional insights such as DUT parameters like shelf life of the DUT such as predicting time to failure. This helps validation engineers in predictive maintenance. As stated above, the system here does not alter the existing customer workflow, rather proposed algorithm learns on the fly as user continue to use the Oscilloscope during their design and validation. This model will give additional insights such as point of failure and decision to choose optimal filters from a large set.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### Examples

Illustrative examples of the technologies disclosed herein are provided below. A configuration of the technologies may include any one or more, and any combination of, the examples described below.

Example 1 is 1 a test and measurement instrument, comprising: one or more ports to connect to a device under test (DUT); a user interface having one or more controls; a display; a storage; and one or more processors configured to execute code that causes the one or more processors to: receive test signals from the DUT through the one or more ports as a test of the DUT; use the test signals to generate test data; display test data on the display; display a control button on the user interface indicating that an artificial intelligence (AI) assistant is available; receive an input through the control button from a user to start the AI assistant; provide regions on the user interface to allow the user to interact with the AI assistant; and upon receiving inputs through the regions on the user interface, apply a machine learning model represented by the AI assistant to provide the user with additional information related to one or more of the test and the DUT.

Example 2 is the test and measurement instrument of Example 1, wherein the code that causes the one or more processors to provide additional information comprises code that causes the one or more processors to provide recommendations for measurement configurations, generate additional results to those the user has selected, recommend additional instruments, and predict time to failure for the DUT or components on the DUT.

Example 3 is the test and measurement instrument of either Examples 1 or 2, wherein the code that causes the one or more processors to provide regions on the user interface comprises code to cause the one or more processors to display AI assistant control buttons at relevant locations on the display.

Example 4 is the test and measurement instrument of Example 3, wherein the one or more processors are further configured to execute code to receive an input through one of the control buttons and react to the input, the code that causes the one or more processors to react to the input comprises code to cause the one or more processors to: automatically perform a recommended action represented by the control button when the input comprises a first input; display steps to allow the user to perform the recommended action when the input comprises a second input; and display an interactive window to allow the user to interact with the AI assistant when the input comprises a third input.

Example 5 is the test and measurement instrument of any of Examples 1 through 4, wherein the one or more processors are further configured to execute code that causes the one or more processors to create and train the machine learning model.

Example 6 is the test and measurement instrument of Example 5, wherein the one or more processors are configured to create and train the machine learning model while the user is using the test and measurement instrument without disrupting the user workflow.

Example 7 is the test and measurement instrument of any of Examples 1 through 6, wherein the code that causes the one or more processors to create the machine learning model comprises code to cause the one or more processors to preprocess the data before the one or more processors collect data comprised of the test data and associated metadata; extract key feature data from the data; analyze the linearity of the key feature data to select an activation function; use the activation function to activate portions of a neural network to build the machine learning model; use a portion of the key feature data to train the machine learning model; and use another portion of the key feature data to validate the machine learning model.

Example 8 is the test and measurement instrument of 7, wherein the one or more processors are further configured to execute code that causes the one or more processors to preprocess the data before extracting key feature data.

Example 9 is the test and measurement instrument of any of Examples 1 through 9, wherein the one or more processors are further configured to execute code to cause the one or more processors to manage storage of the data by auto labeling the data to classify the data, to remove unwanted data, and to compress and serialize the data, then to save the data in real time.

Example 10 is the test and measurement instrument of any of Examples 1 through 9, wherein the one or processors are further configured to execute code to cause the one or more processors to tune the machine learning model during usage of the test and measurement instrument to keep the machine learning model up to date.

Example 11 is a method of employing an artificial intelligence (AI) assistant with a test and measurement instrument, comprising: receiving test signals from the DUT through a port as a test of the DUT; using the test signals to generate test data; displaying the test data on a display; displaying a control button on the user interface indicating that an artificial intelligence (AI) assistant is available; receiving an input through the control button from a user to start the AI assistant; providing regions on the user interface to allow the user to interact with the AI assistant; and upon receiving inputs through the regions on the user interface, using a machine learning model associated with the AI assistant to provide the user with additional information related to one or more of the test and the DUT.

Example 12 is the method of Example 11, wherein providing additional information comprises providing recommendations for measurement configurations, generate additional results to those the user has selected, recommend additional instruments, and predict lifetime expectancy for the DUT or components on the DUT.

Example 13 is the method of either Examples 11 or 12, wherein providing regions on the user interface comprises displaying control buttons at relevant locations on the display of test data.

Example 14 is the method of Example 13, further comprising receiving an input through one of the control buttons and reacting to the input by: performing a recommended action represented by the control button when the input comprises a first input; displaying steps to allow the user to perform the recommended action when the input comprises a second input; and displaying an interactive window to allow the user to interact with the AI assistant when the input comprises a third input.

Example 15 is the method of any of Examples 11 through 14, further comprising creating the machine learning model.

Example 16 is the method of Example 15, wherein creating the machine learning model comprises creating the machine learning model when no machine learning model exists.

Example 17 is the method of Example 15, wherein creating the machine learning model comprises training the machine learning model in real time.

Example 18 is the method of Example 15, wherein creating the machine learning model occurs while the user is using the test and measurement instrument without disrupting the user.

Example 19 is the method of Example 15, wherein creating the machine learning model comprises: collecting the test and associated metadata as data; extracting key feature data from the data; analyzing linearity of the key feature data and selecting an activation function; using the activation function to activate portions of a neural network to build the machine learning model; using a configurable portion of the key feature data to train the machine learning model; and using another configurable portion of the key feature data to validate the machine learning model.

Example 20 is the method of Example 17, further comprising preprocessing the data before extracting key feature data from the data.

Example is the method of any of Examples 11 through 20, further comprising managing storage of the data by auto labeling the data to classify the data, removing unwanted data, and compressing and serializing the data, then saving the data in real time.

Example 22 is the method of any of Examples 1 through 21, further comprising tuning the machine learning model during usage of the test and measurement instrument to keep the model up to date.

Example 23 is the method of Example 15, further comprising sharing the machine learning model across multiple test and measurement endpoints after the machine learning model is created.

Example 24 is the method of Example 23, wherein sharing the machine learning model across multiple endpoints further comprises providing version control as other endpoints update the machine learning model.

Example 25 is the method of any of Examples 1 through 25, further comprising employing a subscription service to allow external users access to adjust and optimize the machine learning model for specific applications and requirements.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement instrument, comprising:
one or more ports to connect to a device under test (DUT);
a user interface having one or more controls;
a display;
a storage; and
one or more processors configured to execute code that causes the one or more processors to:
receive test signals from the DUT through the one or more ports as a test of the DUT;
use the test signals to generate test data;
display test data on the display;
display a control button on the user interface indicating that an artificial intelligence (AI) assistant is available;
receive an input through the control button from a user to start the AI assistant;
provide regions on the user interface to allow the user to interact with the AI assistant; and
upon receiving inputs through the regions on the user interface, apply a machine learning model represented by the AI assistant to provide the user with additional information related to one or more of the test and the DUT.

2. The test and measurement instrument as claimed in claim 1, wherein the code that causes the one or more processors to provide additional information comprises code that causes the one or more processors to provide recommendations for measurement configurations, generate additional results to those the user has selected, recommend additional instruments, and predict time to failure for the DUT or components on the DUT.

3. The test and measurement instrument as claimed in claim 1, wherein the code that causes the one or more processors to provide regions on the user interface comprises code to cause the one or more processors to display AI assistant control buttons at relevant locations on the display.

4. The test and measurement instrument as claimed in claim 3, wherein the one or more processors are further configured to execute code to receive an input through one of the control buttons and react to the input, the code that causes the one or more processors to react to the input comprises code to cause the one or more processors to:
automatically perform a recommended action represented by the control button when the input comprises a first input;
display steps to allow the user to perform the recommended action when the input comprises a second input; and
display an interactive window to allow the user to interact with the AI assistant when the input comprises a third input.

5. The test and measurement instrument as claimed in claim 1, wherein the one or more processors are further configured to execute code that causes the one or more processors to create and train the machine learning model.

6. The test and measurement instrument as claimed in claim 5, wherein the one or more processors are configured to create and train the machine learning model while the user is using the test and measurement instrument without disrupting the user workflow.

7. The test and measurement instrument as claimed in claim 1, wherein the code that causes the one or more processors to create the machine learning model comprises code to cause the one or more processors to preprocess the data before the one or more processors
collect data comprised of the test data and associated metadata;
extract key feature data from the data;
analyze the linearity of the key feature data to select an activation function;
use the activation function to activate portions of a neural network to build the machine learning model;
use a portion of the key feature data to train the machine learning model; and
use another portion of the key feature data to validate the machine learning model.

8. The test and measurement instrument as claimed in claim 7, wherein the one or more processors are further configured to execute code that causes the one or more processors to preprocess the data before extracting key feature data.

9. The test and measurement instrument as claimed in claim 1, wherein the one or more processors are further configured to execute code to cause the one or more processors to manage storage of the data by auto labeling the data to classify the data, to remove unwanted data, and to compress and serialize the data, then to save the data in real time.

10. The test and measurement instrument as claimed in claim 1, wherein the one or processors are further configured to execute code to cause the one or more processors to tune the machine learning model during usage of the test and measurement instrument to keep the machine learning model up to date.

11. A method of employing an artificial intelligence (AI) assistant with a test and measurement instrument, comprising:
receiving test signals from the DUT through a port as a test of the DUT;
using the test signals to generate test data;
displaying the test data on a display;
displaying a control button on the user interface indicating that an artificial intelligence (AI) assistant is available;
receiving an input through the control button from a user to start the AI assistant;
providing regions on the user interface to allow the user to interact with the AI assistant; and
upon receiving inputs through the regions on the user interface, using a machine learning model associated with the AI assistant to provide the user with additional information related to one or more of the test and the DUT.

12. The method as claimed in claim 11, wherein providing additional information comprises providing recommendations for measurement configurations, generate additional results to those the user has selected, recommend additional instruments, and predict lifetime expectancy for the DUT or components on the DUT.

13. The method as claimed in claim 11, wherein providing regions on the user interface comprises displaying control buttons at relevant locations on the display of test data.

14. The method as claimed in claim 13, further comprising receiving an input through one of the control buttons and reacting to the input by:
performing a recommended action represented by the control button when the input comprises a first input;
displaying steps to allow the user to perform the recommended action when the input comprises a second input; and
displaying an interactive window to allow the user to interact with the AI assistant when the input comprises a third input.

15. The method as claimed in claim 11, further comprising creating the machine learning model.

16. The method as claimed in claim 15, wherein creating the machine learning model comprises creating the machine learning model when no machine learning model exists.

17. The method as claimed in claim 15, wherein creating the machine learning model comprise training the machine learning model in real time.

18. The method as claimed in claim 15, wherein creating the machine learning model occurs while the user is using the test and measurement instrument without disrupting the user.

19. The method as claimed in claim 15, wherein creating the machine learning model comprises:
collecting the test and associated metadata as data;
extracting key feature data from the data;
analyzing linearity of the key feature data and selecting an activation function;
using the activation function to activate portions of a neural network to build the machine learning model;
using a configurable portion of the key feature data to train the machine learning model; and
using another configurable portion of the key feature data to validate the machine learning model.

20. The method as claimed in claim 17, further comprising preprocessing the data before extracting key feature data from the data.

21. The method as claimed in claim 11, further comprising managing storage of the data by auto labeling the data to classify the data, removing unwanted data, and compressing and serializing the data, then saving the data in real time.

22. The method as claimed in claim 11, further comprising tuning the machine learning model during usage of the test and measurement instrument to keep the model up to date.

23. The method as claimed in claim 15, further comprising sharing the machine learning model across multiple test and measurement endpoints after the machine learning model is created.

24. The method as claimed in claim 23, wherein sharing the machine learning model across multiple endpoints further comprises providing version control as other endpoints update the machine learning model.

25. The method as claimed in claim 11, further comprising employing a subscription service to allow external users access to adjust and optimize the machine learning model for specific applications and requirements.
